(19) United States
(12) Patent Application Publication
(10) Pub. No.: US 2025/0300106 A1
(43) Pub. Date: Sep. 25, 2025

(54) POWER DEVICES WITH BARRIER METAL EXTENSION AND SEALING

(71) Applicant: Wolfspeed, Inc., Durham, NC (US)

(72) Inventor: Thomas Harrington, Durham, NC (US)

(21) Appl. No.: 18/612,356

(22) Filed: Mar. 21, 2024

(51) Int. Cl. H01L 23/00

(52) U.S. Cl. CPC H01L 24/05; H01L 24/03; H01L 2224/03614; H01L 2224/03622; H01L 2224/05022; H01L 2224/05084; H01L 2224/05124; H01L 2224/05147; H01L 2224/05166; H01L 2224/05181; H01L 2224/05184; H01L 2224/05186; H01L 2224/05647; H01L 2924/0132; H01L 2924/04941; H01L 2924/04953; H01L 2924/13055; H01L 2924/13062; H01L 2924/13091

(57) ABSTRACT

A semiconductor device includes a semiconductor layer (and a metal contact structure on the semiconductor layer, the metal contact structure comprising a first metal layer structure on the semiconductor layer. The first metal layer structure may include a barrier layer and a first metal contact layer on the barrier layer. An outer edge of the first metal contact layer is inset from an outer edge of the barrier layer so that a peripheral portion of the barrier layer extends farther outward than the outer edge of the first metal contact layer.

### FIELD

The present disclosure relates to semiconductor power devices, and in particular to metallizations for power semiconductor devices.

### BACKGROUND

Power semiconductor devices typically have relatively thin topside and backside metallizations. This is the result of a number of factors, including metal deposition process capabilities, process time and cost, and stress induced warpage of the wafer. For high current power devices, however, these thin metallization layers introduce limitations to performance and reliability of the product. This is particularly so for wide band gap devices which offer considerably higher potential current densities. These higher densities require advancements in the devices and their associated packages to achieve their full potential.

The presence of thin layers may limit performance and reliability at both the device and package levels. For example, at the device level, thin metal layers may result in high current concentrations, uneven current distribution, localized heating and/or localized thermal stresses. At the package level, thin metal layers may result in limitations in the power interconnection size (wire diameter, ribbon thickness, etc.), limitations in the power interconnection material (softer materials vs. harder materials), a higher risk of device damage during wire/ribbon bonding, localized thermal stresses at the interconnection interface and/or limiting the allowable current (i.e. the device is not fully utilized).

Thicker metallization, particularly on the topside metal layer, may help address these issues on multiple fronts. For example, the use of thicker metallization (particularly top side metallization) may allow buffering the current to a more even distribution, and/or may reduce the localized heating and spreading it away from critical interfaces. Additionally, the use of thicker metallization may help to improve robustness for larger size power interconnections and/or may provide a capability to apply compatible materials for different power interconnection materials.

Creating the thicker metallization on a semiconductor wafer, however, has challenges which limit to what is practical and possible. Wafers are relatively thin at the time of processing, and may encounter multiple high temperature conditions as the devices are formed. Thicker metal layers, particularly if only on one side, can introduce warpage and distortion that are often too high for usage.

### SUMMARY

A semiconductor device according to some embodiments includes a semiconductor die and a metal contact structure on the semiconductor die, the metal contact structure comprising a first metal layer structure on the semiconductor die. The first metal layer structure may include a barrier layer and a first metal contact layer on the barrier layer. An outer edge of the first metal contact layer is inset from an outer edge of the barrier layer so that a peripheral portion of the barrier layer extends farther outward than the outer edge of the first metal contact layer.

The semiconductor device may further include a protective layer on the peripheral portion of the first metal contact layer and the outer edge of the barrier layer.

The protective layer may include a passivation layer on the peripheral portion of the first metal contact layer and the outer edge of the barrier layer.

The semiconductor device may further include a polyimide layer on the passivation layer.

The protective layer may include a polyimide layer on the peripheral portion of the first metal contact layer and the outer edge of the barrier layer.

The barrier layer may include a first barrier layer, and the second metal layer structure may include a second barrier layer on the first metal contact layer and a second metal contact layer on the second barrier layer.

The first barrier layer and the second barrier layer comprise titanium.

The first barrier layer may include titanium nitride and the second barrier layer may include titanium tungsten.

The first metal contact layer and the second metal contact layer comprise copper, and the first barrier layer and the second barrier layer comprise titanium tungsten.

The first barrier layer may be formed on an interlayer dielectric layer, and the semiconductor device may further include an ohmic contact on the semiconductor die. The semiconductor device may further include a conductive via that electrically connects the first metal contact layer and the ohmic contact.

The barrier layer and the first metal contact layer extend into the conductive via.

The conductive via may include a conductive plug. The conductive plug may include tungsten.

The first metal contact layer may include copper, and the barrier layer may include titanium. The second metal contact layer may include copper. The first metal contact layer may include aluminum copper.

A method of forming a semiconductor device includes providing a semiconductor layer, providing an interlayer dielectric layer on the semiconductor layer, providing an intermediate layer on the interlayer dielectric layer, providing a metal layer on the intermediate layer, wherein an outer edge of the metal layer overhangs an outer edge of the intermediate layer, and isotropically etching the metal layer at least until the outer edge of the metal layer no longer overhangs the outer edge of the intermediate layer.

Isotropically etching the metal layer may expose a peripheral portion of the intermediate layer.

The method may further include forming a protective layer on the semiconductor layer, the protective layer contacting the interlayer dielectric layer, the intermediate layer and the metal layer.

The protective layer may include a passivation layer on the outer edge of the metal layer and the outer edge of the intermediate layer.

The method may further include forming a polyimide layer on the passivation layer.

The protective layer may include a polyimide layer on the peripheral portion of the intermediate layer and the outer edge of the metal layer.

The intermediate layer may include a first intermediate layer and the metal layer may include a first metal layer, the method further including providing a second metal layer structure on the first metal layer, the second metal layer structure comprising a second intermediate layer on the first metal layer and a second metal layer on the second intermediate layer.

The first intermediate layer and the second intermediate layer comprise titanium nitride, titanium tungsten and/or tantalum nitride.

The first intermediate layer may include titanium nitride and the second intermediate layer may include titanium tungsten.

The first metal layer and the second metal layer comprise copper, and wherein the first intermediate layer and the second intermediate layer comprise titanium tungsten.

The semiconductor device may further include an ohmic contact on the semiconductor layer, and the semiconductor device may further include a conductive via that electrically connects the metal layer and the ohmic contact.

The intermediate layer and the metal layer may extend into the conductive via.

The conductive via may include a conductive plug of, for example, tungsten.

The metal layer may include copper, and the intermediate layer may include titanium nitride, titanium tungsten and/or tantalum nitride. In some embodiments, the metal layer may include aluminum copper.

A method of forming a semiconductor device incudes providing a semiconductor layer, providing an interlayer dielectric layer on the semiconductor layer, providing a preliminary intermediate layer on the interlayer dielectric layer, and providing a preliminary capping layer on the preliminary intermediate layer. The preliminary capping layer and the preliminary intermediate layer are etched to define a capping layer and an intermediate layer. Etching the preliminary metal layer and the preliminary intermediate layer causes an outer edge of the capping layer to overhang an outer edge of the intermediate layer. The method further includes etching the capping layer at least until the outer edge of the capping layer no longer overhangs the outer edge of the intermediate layer.

Etching the capping layer may expose a peripheral portion of the intermediate layer.

The method may further include forming a protective layer on the semiconductor layer, wherein the protective layer contacts the interlayer dielectric layer, the intermediate layer and the capping layer.

### BRIEF DESCRIPTION OF THE DRAWINGS

FIG. 1 illustrates an example of a MOSFET device.

FIG. 2 illustrates an example of a MOSFET circuit.

FIGS. 3, 4 and 5 illustrate a cross-sectional views of MOSFET devices including a plurality of MOSFET cells.

FIG. 6 illustrates semiconductor wafers experiencing various forms of warpage.

FIG. 7 illustrates a semiconductor device according to some embodiments.

FIGS. 8A and 8B, 9 and 10 illustrate metal stacks on a semiconductor device according to some embodiments.

FIG. 11 illustrates a detail of an end portion of a metal stack of a semiconductor device.

FIG. 12 illustrates a detail of an end portion of a metal stack of a semiconductor device according to some embodiments.

FIGS. 13A-13D illustrate operations of forming a device 100 according to some embodiments.

FIG. 14 illustrates a detail of an end portion of a metal stack of a semiconductor device.

FIG. 15 illustrates a detail of an end portion of a metal stack of a semiconductor device according to some embodiments.

FIG. 16 illustrates a detail of an end portion of a metal stack of a semiconductor device.

FIG. 17 illustrates a detail of an end portion of a metal stack of a semiconductor device according to some embodiments.

### DETAILED DESCRIPTION OF EMBODIMENTS

Wide Band Gap power devices, including devices based on silicon carbide (SiC), gallium nitride (GaN), and the like offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, several challenges must be addressed both at the device and the package level, including the formation of electrical interconnections from the device topsides to the package substrate or terminals. Other challenges include waste heat removal, including conduction and switching losses from the devices, and effective electrical isolation between high voltage potentials. Wide bandgap power devices should also have the capability to handle high steady state currents, capability to handle high transient current events, mechanical robustness to reliably operate in high stress, high temperature, high vibration environments. Such devices should be compatible with advanced interconnection materials, structures, and techniques, as well as with advanced device attach materials, structures, and techniques.

Power packages contain power semiconductor devices, including MOSFETS, JFETs, IGBTs, diodes, and the like, arranged into a variety of circuit topologies. A device package serves many functions, including electrical interconnection, electrical isolation, heat transfer, and mechanical structure. The package protects devices from environmental contamination and moisture, and provides external electrical and thermal connection interfaces. The package should also provide compliance with safety standards, such as voltage creepage and clearance distances.

Generally speaking, power packages can be categorized as either a discrete package, housing a single device, or a power module, housing multiple devices. Power modules may place multiple devices in parallel and arrange them into various circuit topologies. As an example, a single switch position package that houses one device would be categorized a discrete, and one that houses multiple devices in parallel (to increase output current) would be considered a power module.

Packages conventionally use, but are not limited to, some combination of the following components, each providing multiple functions. These are summarized in the following table. The terms used in this disclosure, unless otherwise indicated, follow the definitions outlined in Table 1 below.

TABLE 1
Definitions

| Item | Description |
|---|---|
| Power Device(s) | Controllable switches MOSFET, IGBT, and the like and Diodes |
| Substrate, Power | Layered metal and ceramic for high current electrical interconnection, |
| | high voltage isolation, high thermal conductivity, coefficient of thermal |
| | expansion (CTE) matching, and external thermal interface |
| Substrate, Signal | Layered Printed Circuit Board (PCB), layered metal and ceramic, thick |
| | film, and the like for high frequency electrical interconnection and high |
| | voltage isolation |
| Terminal, Power | Metal contact for high current external connection and internal |
| | interconnection |
| Terminal, Signal | Metal contact or connector for high frequency external connection and |
| | internal interconnection |
| Lead Frame | Metal contact strip for high current external connection and internal |
| | interconnection; Contacts are joined together on a single sheet, often |
| | with multiple products per sheet, and are processed as an array and then |
| | formed and singulated |
| Base Plate | Metal or composite material for mechanical structure, high thermal |
| | conductivity, coefficient of thermal expansion (CTE) matching, and |
| | external thermal interface |
| Device Attach | Solder, adhesive, or sintered metal, and the like for mechanical structure, |
| | high current interconnection, and high thermal conductivity |
| Terminal Attach | Solder, adhesive, sintered metal, laser weld, ultrasonic weld, and the like |
| | for mechanical structure, high current interconnection, and high thermal |
| | conductivity |
| Substrate Attach | Solder, adhesive, or sintered metal, and the like for mechanical structure |
| | and high thermal conductivity |
| Interconnection | Conductive element forming an electrical connection between one |
| | electrical node and another |
| Wire Bonds, Power | Ultrasonically or thermosonically bonded large diameter wire, ribbon, |
| | and the like for high current electrical interconnection |
| Wire Bonds, Signal | Ultrasonically or thermosonically bonded small diameter wire, ribbon, |
| | and the like for low current electrical interconnection |
| Case/Housing | Injection molded case and lid, providing mechanical structure, high |
| | voltage isolation, and acting as a well for the encapsulation material |
| Mold Compound | Transfer or compression molded epoxy molding compound (EMC) for |
| | mechanical structure, high voltage isolation, coefficient of thermal |
| | expansion (CTE) matching, and low humidity absorption |
| Encapsulation | Soft, flexible silicone or similar encapsulation material for high voltage |
| | isolation, and low humidity absorption |
| Temperature Sensor | Passive or active element that can be used to monitor internal |
| | temperatures |
| Signal Circuitry | Resistors, capacitors, surface mount components, sensors, and the like |
| | for stabilization of the dynamic switching performance of the devices or |
| | for other internal circuit requirements, such as active miller clamping, |
| | etc. |

Some typical design requirements for power device packages include high power density (small package size), high current, high voltage, high temperature operation, low thermal resistance, low stray inductance, fast and clean switching, high efficiency through low on-resistance, high efficiency through high speed switching, thoughtful external terminal layout for effective interconnection, compliance with creepage and clearance standards, moisture sensitivity level (MSL) compliance, and low cost.

A power semiconductor device is typically vertical, meaning power flows from top the backside to the topside of the chip (or vice versa). While there are many types of power devices where this technique applies, a MOSFET will be used for the purposes of explanation and illustration.

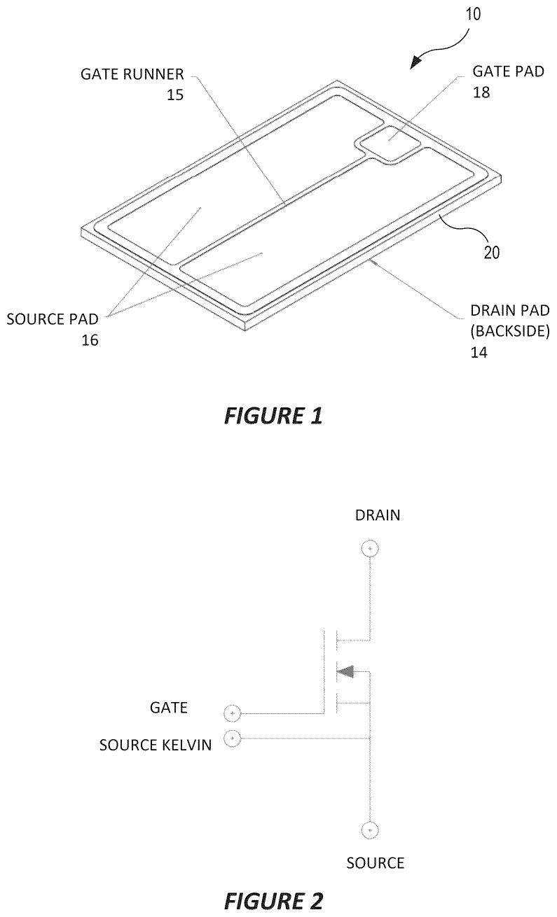

A power MOSFET is a three terminal device: (1) gate, (2) source, and (3) drain. Often an additional kelvin connection to the source terminal is made to optimize switching performance to isolate the power and signal loops. The gate and source are located on what will be referred to as the device topside, while the drain is located on the device backside. The high current path flows from the drain to source or source to drain, through the area of the device. An example MOSFET device is depicted in FIG. 1, and an example MOSFET circuit element is depicted in FIG. 2.

Referring to FIGS. 1 and 2, a MOSFET device 10 generally includes source, gate and drain terminals. The source terminal is connected to a pair of source pads 16 on the front or top side of a semiconductor die 20, and the gate terminal is connected to a gate pad 18 on the front or top side of the die 20. A gate runner 15 extends from the gate pad 18 and distributes the gate signal across the die 20. The drain terminal is connected to a drain pad 14 on the back side of the die 20.

The topside and backside metallizations that form the source pads 16, the gate pad 18 and the drain pad 14 generally include stack of metals to provide a variety of functions, such as ohmic contact, diffusion barrier, seed layers for plating or adhesion, and a capping bonding layer. The topside bonding layer is generally the thickest and is designed to be metallurgically compatible with the desired topside interconnection method. For example, the topside bonding layer may be aluminum to be most compatible with aluminum wire bonding or copper to be compatible with copper wire bonding. The backside metallization is also a stack of metals serving similar functions. Backside attaches tend to be a soldered, brazed, or sintered, rather than connected to wire bonds. The thickness of each layer is generally selected based on what is practical and cost effective to fabricate, what operating conditions are expected, and what performance requirements must be met.

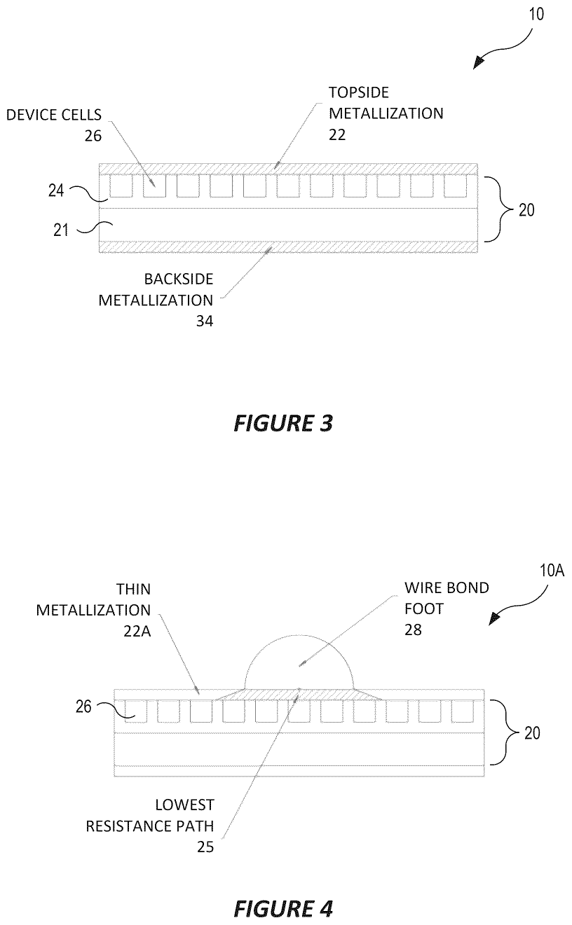

While a power semiconductor device operates as a single device, the physical chip layout is a large array of paralleled device ‘cells’ interconnected through the topside metallization and other functional layers. This is illustrated in FIG. 3 showing a sectional view of a power semiconductor device 10 including a substrate 21 and an epitaxial layer 24 in which a plurality of device cells 26 are formed. The power semiconductor device 10 may, for example, be a MOSFET device. A backside metallization 34 is formed on the back, or bottom side of the die 20, and a topside metallization 22 is formed on the front, or top side of the die 20.

Note that there are many more features and functional layers than depicted in FIG. 3 for simplicity, and the layers are not to scale to show detail. The device cells 26 are paralleled through the topside source metallization 22. The bulk of the semiconductor material is used for voltage isolation, with the backside metallization 34 providing electrical contact to the drain. Current flows vertically through the device from the part of the topside metallization 22 forming the source to the backside metallization 34 forming the drain.

In many cases, only a portion of the source pad 16 can be used for interconnection through wire bonds or ribbons. Hence, current must spread from these sites out towards the device cells 26. To effectively obtain the most performance out of the device 10, each of these cells 26 should be fully utilized by carrying as much current as possible. Accordingly, distributing the current from the interconnection sites to each and every cell 26 is important for full device utilization. Distributing current equally among the cells also helps to spread heat evenly across the device.

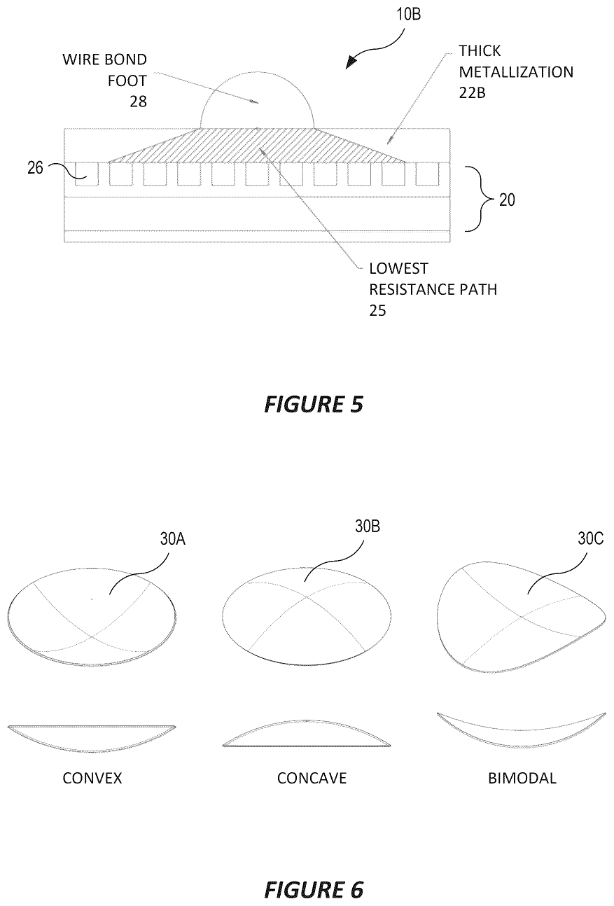

Using thicker metal may reduce the sheet resistance of the topside metallization 22, and may provide more cross sectional area through which current can readily spread. Increasing the thickness of the topside metallization layer 22 may allow for more cells to access a low resistance, efficient path to the input and output sites for current flow. This buffering effect may reduce high current concentrations and/or may reduce localized heating at the bonding interfaces. FIGS. 4 and 5 depict the buffering effect for thin (FIG. 4) topside metallizations 22A and thick (FIG. 5) topside metallizations 22B. Note that the device structure and scale of the image are used for description purposes and are not true to structure or scale for an actual device and package. A wire bond foot 28 is provided on the topside metallizations 22A, 22B, and current from the wire bond foot 28 flows into the die 20 via a lowest resistance path 25.

With a thin metallization 22A, there is limited room to laterally spread current and the resulting heat at the interface. These localized high current and heat densities can act to stress and weaken the interface. A thicker metallization 22B helps to buffer the current and heat to better distribute the energy away from the interfaces and evenly towards the device cells 26.

The application of a thicker topside metal may also improve device robustness for more aggressive interconnection methods. For example, copper wire is substantially harder than aluminum, and could cause damage to the sensitive device during the wire bonding process. Thicker metals can buffer out the energy applied to form the metallurgical bonds, and a ‘cushioning’ effect adding resilience and wider process windows. Thus, it may be preferable for the thicker topside metal 22A, 22B to improve the performance and bondability of copper wires. Moreover, due to the high conductivity of copper, the use of copper in the topside metal 22A, 22B can enable the use of fewer wire bonds, or may allow higher currents for a given number of wire bonds. The use of thick topside metal may also accommodate larger wire bond footprints, which can allow for more current.

While there are numerous benefits to thicker metallization layers, there are also many processing challenges. For example, there is a large coefficient of thermal expansion (CTE) imbalance between the semiconductor wafer and the metal layers. As the wafer experiences exposures to high temperatures during processing, the metal and semiconductor expand and contract at different rates, creating thermal stress. These thermal stresses can manifest as warpage of the wafer once cooled.

Warpage is a major problem which may reduce yield or render the wafer useless for further processing. Various types of warpage of wafers 30 are illustrated in FIG. 6. Depending on the temperature delta, metal layout, wafer thickness and diameter, and other factors, a warped wafer could be convex (30A), concave (30B), or bimodal (30C), as shown in

FIG. 6. The risk of warpage exceeding a usable level increases as the metal thickness increases. This is particularly so if it is only increased on one side of the device.

### Selective Topside Metallization

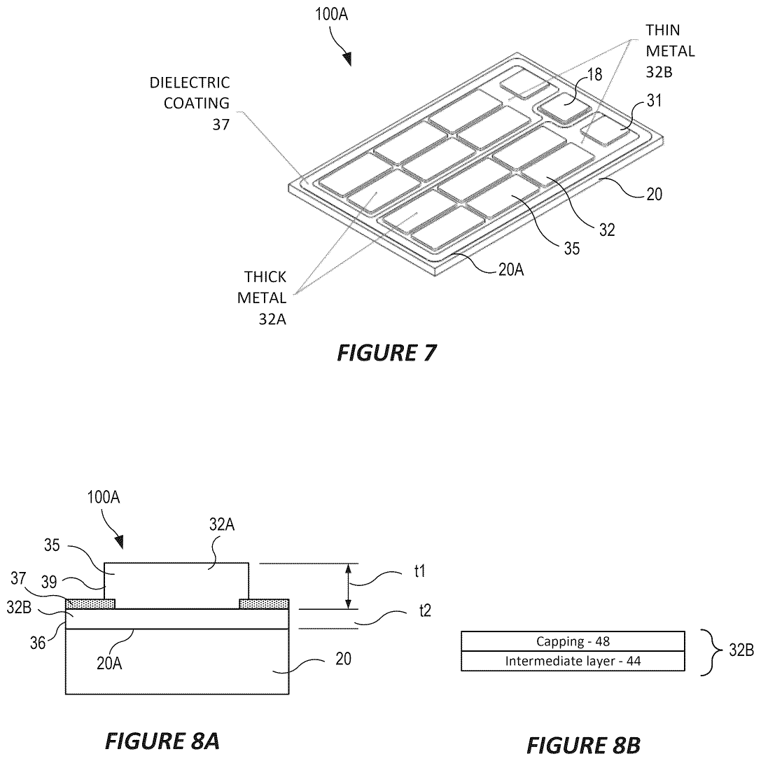

To address the issue of wafer warpage while delivering the benefits of thick metallization, some embodiments apply thick metal selectively using multiple masked deposition processes. That is, instead of applying thick metal on all conductive surfaces, the thick metal is applied selectively only where it is needed. These localized thick plateaus of metal provide buffering and robustness but are small enough that the metal loading is greatly reduced, and the expansion stresses are lessened. This approach is shown on an example power device in FIGS. 7, 8A and 8B. A section view is also presented. Note that there are many functional layers in the sectional view that are not shown for simplicity. Embodiments are described herein in the context of MOSFET power semiconductor devices. However, it will be appreciated that the inventive concepts may be applied to many different types of semiconductor devices, such as JFETs, IGBTs, diodes, and other devices.

Referring to FIGS. 7, 8A and 8B, a semiconductor MOSFET device 100A according to some embodiments includes a semiconductor die 20 on which a topside metallization 32 is formed on an upper surface 20A of the device 10. The top side metallization 32 includes a first metal layer 32B formed on an upper surface 20A of the die 20, and a second metal layer 32A formed on the first metal layer 32B. The first metal layer 32B and the second metal layer 32A may together form, for example, a source contact of the semiconductor device 100A. As used herein in reference to metal layers, the terms “thick” and “thin” refer to the dimension of the metal layer as measured in a direction normal to the surface on which the metal layer is formed, such as the upper surface 20A of the semiconductor die 20. Thus, for example, the thick metal layer 32A has a thickness t1, while the thin metal layer 32B has a thickness t2 as illustrated in FIG. 8A.

Referring still to FIGS. 7, 8A and 8B, a dielectric coating 37 may be formed on portions of the upper surface 20A of the die 20 not covered by the second metal layer 32A. The second metal layer 32A may include a metal, such as copper or aluminum, that is suitable for connection by a wire bond (not shown). The second metal layer 32A is formed as a plurality of discrete thick metal regions on the first metal layer 32B. The discrete thick metal regions may serve as bond pads 35 of the device 100A. That is, the bond pads 35 are physically separated from one another and are mechanically and electrically connected to one another only through the first metal layer 32B. The bond pads 35 include a plurality of source wire bond pads, or source bond pads. The bond pads 35 also include a source kelvin bond pad 31 to facilitate a source kelvin connection to the device input signal line as shown in FIG. 2.

The second metal layer 32A is formed where needed for a desired performance, interconnection scheme, and interconnection material. It may be deposited through similar processes as the first metal layer 32B. A mask or similar may be used to only apply the metal where desired to form the bond pads 35. The bond pads 35 may also be formed by plating a thick layer of metal over the first metal layer 32B over and etching the plated metal to form the bond pads 35. Plating is a practical and cost effective to form relatively thick layers.

The first metal layer 32B may have a thickness of about 1 microns to 5 microns, while the second metal layer 32A may have a thickness of about 20 microns or more. In some embodiments, the thick metal layer 32A may have a thickness that is at least 1.5 times the thickness of the thin metal layer. In further embodiments, the thick metal layer 32A may have a thickness that is at least 2 times the thickness of the thin metal layer. In still further embodiments, the thick metal layer 32A may have a thickness that is at least 5 times the thickness of the thin metal layer. In still further embodiments, the thick metal layer 32A may have a thickness that is at least 10 times the thickness of the thin metal layer. In still further embodiments, the thick metal layer 32A may have a thickness that is at least 20 times the thickness of the thin metal layer.

By forming a thin layer of metal on the semiconductor die 20, the design rule for manufacturing the semiconductor die 20 may be tightened, which means that it maybe possible to form smaller or more dense features in the semiconductor die 20 than would be possible if only a single thick metal stack were formed thereon. It will be appreciated that the design rule for a semiconductor die determines how closely or densely features can be formed on the die. When the initial metal layer on the die is thick, a larger design rule is required due to lateral variations in the thick metal layer to discourage the initial metal layer from undesirably contacting unintended features on the die. According to some embodiments, by forming an initial metal layer as a thin layer 32B having a thickness of less than 5 microns, the design rule for the semiconductor die may be reduced.

As seen in FIG. 8A, the second metal layer 32A may be formed so that the side walls of the bond pads 35 are inwardly recessed from the sidewalls of the first metal layer 32B. That is, the outside edges 39 of the bond pads 35 may not reach all the way to the outside edges 36 of the first metal layer 32B. As used herein with respect to metal layers, the term “edge” refers to the outer sidewall, outer surface or outer portion of the metal layer.

Referring to FIG. 8B, the first metal layer 32B may be part of a first layer metal stack which typically includes a capping metal 48 and one or more intermediate layers 44 between the capping layer 48 and the semiconductor die 20. These layers may be deposited through a number of processes, including but not limited to evaporation, sputtering, plating, and the like. The capping layer 48 may be a metal that is metallurgically compatible with the desired material for the second metal layer 32A, which typically includes copper but may include aluminum. For example, the capping layer 48 may include copper, aluminum, aluminum copper (AlCu), aluminum silicon copper (AlSiCu), or any other suitable metal.

The second metal layer 32A may include a material with a high mechanical strength. Generally, copper may be desirable to use for the second metal layer 32A, due to its mechanical strength and/or hardness, to support the formation of copper wire bonds to the bond pads 35. The force of forming a wire bond to the bond pad 35 may displace softer metals, such as aluminum, pushing it to undesired locations on the die.

Copper is also desirable for use as the second metal layer 32A due to its high electrical and thermal conductivity. However, in some cases other metals may be desirable. The second metal layer 32A may be left bare, or in some cases it may be further plated with a more oxidation resistant material such as nickel, palladium, gold, etc. The second metal layer 32A may also have an underlying metal layer or layers as part of its stack, for example, an underlying nickel layer to improve stress buffering for the first metal layer 32B.

The intermediate layer 44 may include a diffusion barrier layer which serves the purpose of obstructing inter-diffusion of soluble metals. As an example, if the capping layer 48 contains copper, then without a diffusion barrier, copper may spread into and contaminate the underlying metals and may also likely diffuse into the underlying insulating layers, interconnects, gate oxides, and substrate of the die 20. This ultimately may inhibit or destroy the function of the device 100A. Adding an insoluble diffusion barrier layer of, for example, TiN, may obstruct this from occurring. The intermediate layer may include other layers, such as adhesion layers, seed layers, etc.

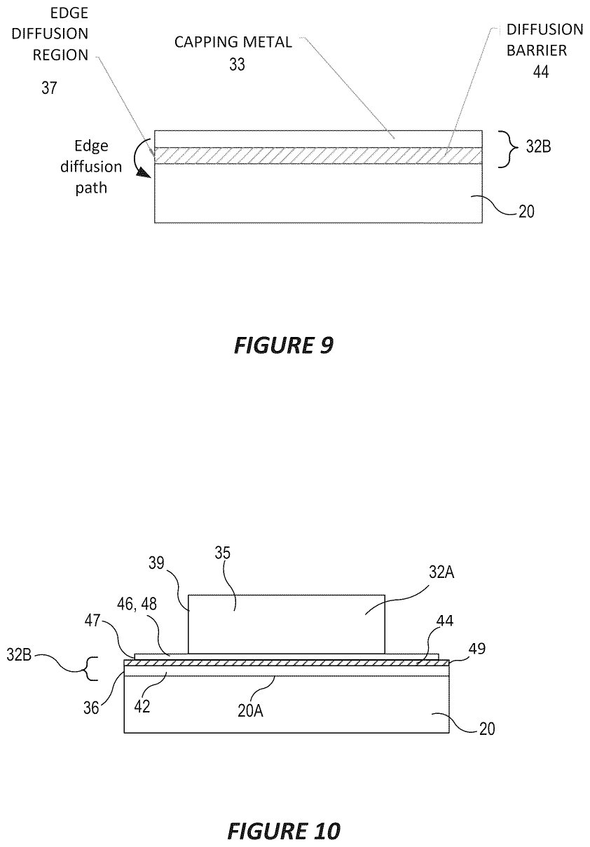

Even if a diffusion barrier is used, however, diffusion may still be possible at the edges of the interface. That is, metal can diffuse around the edges where there is no diffusion barrier in the vertical direction. This is illustrated in FIG. 9, which shows a capping layer with regions 29 where edge diffusion could occur (left) from a capping layer 33 to the die 20.

FIG. 10 illustrates a selective approach in which the seed layer 46 and capping layer 48 are inset from the edges of the diffusion barrier layer 44. That is, edges 47 of the seed layer 46 and capping layer 48 do not extend all the way to the edge 49 of the diffusion barrier layer 44. This may reduce the possibility of edge diffusion from the seed and copper layers 46, 48 into the die 20.

Moreover, the bond pad 35 of the second metal layer 32A is inset such that the edge 49 diffusion barrier layer 44 extends past the edge 39 of the bond pad 35 to further reduce the possibility of edge diffusion from the bond pad 35.

Barrier metal layers are commonly used under primary metallization layers in discrete power and in integrated circuit technologies, both in silicon and in wide bandgap (WBG) technologies, to obstruct the primary metallization, or a constituent element in the primary metallization, from diffusing into other layers. For example, a TiN layer is commonly used under Tungsten (W) filled contacts to prevent tungsten from diffusing into silicon or WBG materials where it can cause lattice damage, potentially resulting in leakage current in the device. A TiN layer is also commonly used under Al or AlCu-filled contacts to obstruct Al from diffusing into the underlaying substrate and to obstruct Cu from diffusing into metal-oxide semiconductor field effect transistor (MOSFET) or complementary MOS (CMOS) gate oxides where it can cause gate oxide failure, potentially resulting in a reduction in lifetime of the device. In technologies where Cu is a primary metallization, a TiW or TaN or TiN layer may be used under the Cu layer to prevent Cu migration into underlying oxides.

In non-damascene technologies, where the primary metallization or the seed layers to the plated primary metallization are patterned by etching the metal itself, the underlying barrier metal layer edge is often undesirably etched back (which can be caused by the overetch required to clear the barrier metal layer over the entire surface of a wafer or by a post etch clean that preferentially attacks the barrier metal or by use of an isotropic wet etch to etch the barrier etch) so that the barrier metal edge is physically pulled-back from the primary metal edge, that is, the barrier metal edge is recessed under the primary metal edge. Depending on the amount of the recess, a passivation layer deposited over the primary metal edge may fail to seal the gap under the primary metal edge, resulting in a void under the primary metal and providing a path for the primary metal and/or its constituent elemental metals to diffuse out from the void and contaminate other layers, including critical oxide layers and the substrate.

Some embodiments described herein provide a method of avoiding the recess of the barrier metal by implementing a second primary metal etch (via an isotropic etch, typically a wet etch) on the unmasked metal layers after the barrier metal etch has completed and after the photo pattern (etch mask) has been removed. The second primary metal etch acts to etch back the sides, corners, and top of the primary metal. When the sides of the primary metal are etched back, the recess of the barrier metal is eliminated, and the edges of the primary metal and the barrier metal are either aligned, or an extension of the barrier metal beyond the primary metal layer (e.g., a barrier metal protrusion, or “foot”) is created. This allows for a subsequent passivation layer (e.g., SiO2, SiN, polyimide, other passivation materials, or a combination of such materials) to more completely seal the edges of the primary metal and the barrier metal, thereby obstructing any undesirable outdiffusion of metals into interfaces, critical oxide layers and semiconductor materials.

The second primary metal etch (also an isotropic etch, and typically a wet etch) is selective to the primary metal. That is, the second etch process does not etch the barrier metal, but only etches the primary metal. Thereby, the second etch process on the unmasked metal layers may remove any barrier metal undercut. The second primary metal etch process occurs after the metal photo pattern (i.e., the etch mask used to initially pattern the barrier layer and primary metal layer) has been removed, after the first metal etch of both the primary metal layer and the underlying barrier layer has caused an undercut in the barrier layer resulting in a void under the primary metal layer.

Some embodiments described herein may eliminate of the barrier layer undercut by creating a barrier layer extension or protrusion (“foot”) that is self-aligned and created without introducing a further photomasking operation. This may be accomplished without the need for an additional photomask step as may be previously required. Moreover, according to some embodiments, the barrier layer extension that is created by the second etch process is self-aligned to the primary metal layer, which may allow for the use of smaller design rules during production of the device.

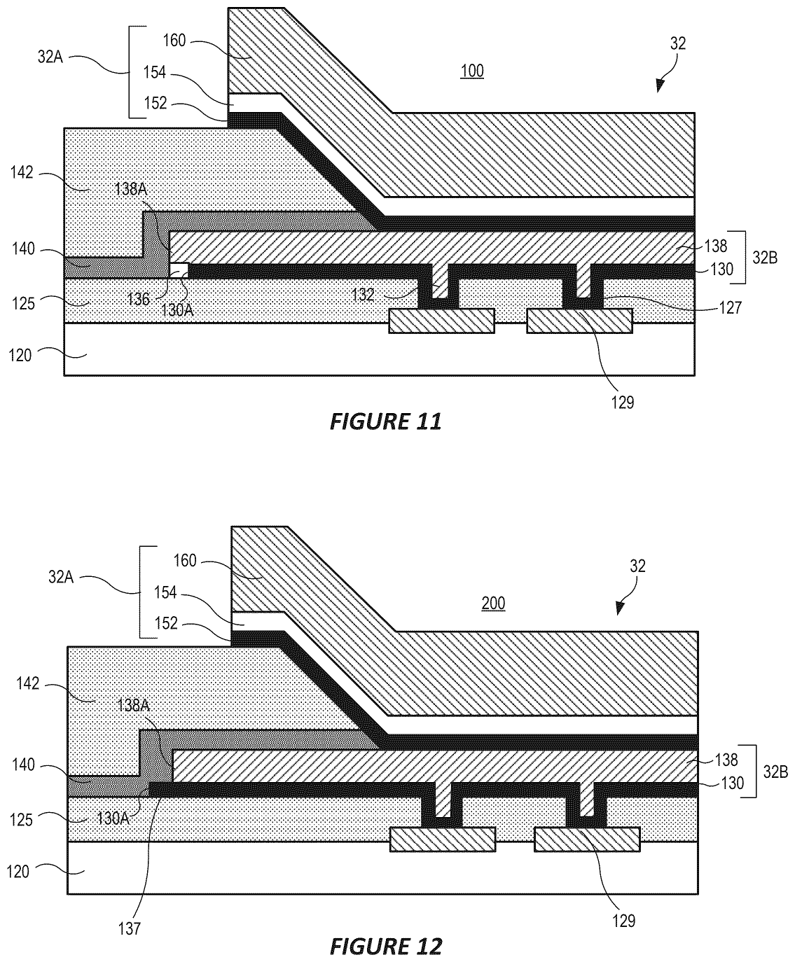

FIG. 11 illustrates a detail of an end portion of a metal stack of a semiconductor device 100. An interlayer dielectric layer 125 is formed on a semiconductor die 120. Ohmic contacts 129 are formed on the semiconductor die 120. The ohmic contacts 129 may, for example, be source contacts, gate contacts or other contacts of the semiconductor device 100. The ohmic contacts 129 may, for example, be silicide regions that at least partially extend into the semiconductor die 120. A metal stack 32 including a first metal layer 32B and a second metal layer 32A is formed on the interlayer dielectric layer 125. The interlayer dielectric layer 125 includes one or more vias 127 therethrough. Portions 132 of the first metal layer 32B extend through the vias 127 to conductively contact the ohmic contacts 129.

The first metal layer 32B includes an intermediate layer 130 and a capping layer 138 on the intermediate layer 130. The intermediate layer 130 may include a material such as titanium (Ti), tungsten (W), tantalum (Ta), TaN, TiN, and/or TiW, which are capable of blocking or impeding the diffusion of metals such as copper, silver, nickel or aluminum that may be harmful to the semiconductor die 120. The capping layer 138 may include a highly conductive metal, such as copper, aluminum, or an alloy thereof.

The edges of the first metal layer 32B are protected by a protective structure that may include a passivation layer 140 that is on the interlayer dielectric layer 125 and that extends onto end portions of the first metal layer 32B.

In some embodiments, the passivation layer 140 may not be present. If the passivation layer 140 is not present, a protective layer 142 of, for example, polyimide, may serve as both passivation and mechanical/environmental protection. The protective layer 142 also provides the seal for Cu metal migration if no gap in barrier metal is present.

Typically, the passivation layer 140 may be provided when the first metal layer 32B is Al (or AlCu or AlSiCu), and the passivation layer 140 is not used when the first metal layer 32B is Cu. However, it is possible to omit the passivation layer 140 even if the first metal is Al or AlCu or AlSiCu.

When present, the passivation layer 140 may include a material such as silicon oxide, silicon nitride, silicon oxynitride, etc., that is provided to protect underlying structures from moisture, contamination, and mechanical damage. A protective layer 142 of a material such as polyimide is provided on the passivation layer 140. The protective layer 142 may provide additional mechanical and/or environmental protection for the underlying device structure, as well as providing a layer that can be planarized to facilitate subsequent processing steps.

An opening is formed in the passivation layer 140 and the protective layer 142 to expose the first metal layer 32B, and the second metal layer 32A is formed in the opening to contact the first metal layer 32B. The second metal layer 32A may include a barrier layer 152, a seed layer 154 and a bond layer 160. The barrier layer 150 may include a material such as titanium (Ti), tungsten (W), tantalum (Ta), TaN, TIN, and/or TiW. The seed layer 154 may include a thin layer of material, such as copper, that can act as a seed for forming a thick copper bond layer 160 thereon.

To form the metal stack 32, after formation of the interlayer dielectric layer 125 and the via openings 127, the intermediate layer 130 and the capping layer 138 are blanket deposited over the semiconductor die 120. An etch mask is then formed over the capping layer 138 and patterned.

When the first metal layer 32B is an etchable material such as an Al-containing layer, then with the etch mask in place, the intermediate layer 130 and capping layer 138 are etched to selectively expose portions of the interlayer dielectric layer 125.

During the etch process, the intermediate layer 130 may etch slightly faster than the capping layer 138, resulting in the formation of a slight overhang of the outer edge 138A of the capping layer 138 relative to the edge 130A of the intermediate layer 130 and creating a slight gap 136 beneath the capping layer 138. The use of an ashing process to clean the photoresist mask from the structure can also result in some overetching of the intermediate layer 130.

When the passivation layer 140 is conformally formed over the structure, the gap 136 may remain. The gap 136 may create a diffusion path for metal atoms, such as copper atoms, in the capping layer 138 to migrate into the interlayer dielectric layer 125 and contaminate the semiconductor die 120, potentially resulting in damage to the device that may reduce the reliability and/or lifetime of the device.

When the first metal layer 32B is a non-preferentially etchable layer such as Cu, the etch mask is inverted, with gaps where the Cu metal will be, and Cu is plated up in those exposed regions, plating onto the seed Cu layer.

For a plated-metal process, the recess or gap 136 adjacent the intermediate layer 130 is primarily caused because the barrier layer etch is an isotropic wet etch which etches laterally at the same time that it is etching downward, resulting in a recess of the intermediate layer 130 under the Cu capping layer 138.

For a non-plated metal process (such as Al sputtering), the recess 136 of the intermediate layer 130 may be caused by an extended barrier layer etch time required to clear the barrier from the entire wafer, or it can be caused by a post-etch cleanup (e.g., a plasma clean) that unintentionally etches the barrier layer, resulting in the recess.

Referring to FIG. 12, according to some embodiments, the intermediate layer 130 and capping layer 138 are formed so that a peripheral edge portion 137 of the intermediate layer 130 extends at least as far outward than the outer edge 138A of the capping layer 138. In some embodiments, the intermediate layer 130 and capping layer 138 are formed so that a peripheral edge portion 137 of the intermediate layer 130 extends farther outward than the outer edge 138A of the capping layer 138 to form a protrusion, or foot 137, on the interlayer dielectric layer 125.

When the passivation layer 125 is conformally formed over the interlayer dielectric layer 125 and the first metal layer 32B, the passivation layer 125 may contact an end surface 130A of the of the intermediate layer 130 as well as an outer edge 138A of the contact layer 138, thereby avoiding the formation of a gap through which metal from the contact layer 138 could migrate. By reducing the ability of harmful metal atoms to migrate toward the semiconductor die 120, contamination of the semiconductor die 120 may be reduced and the operation and/or lifetime of the device 100 may be improved.

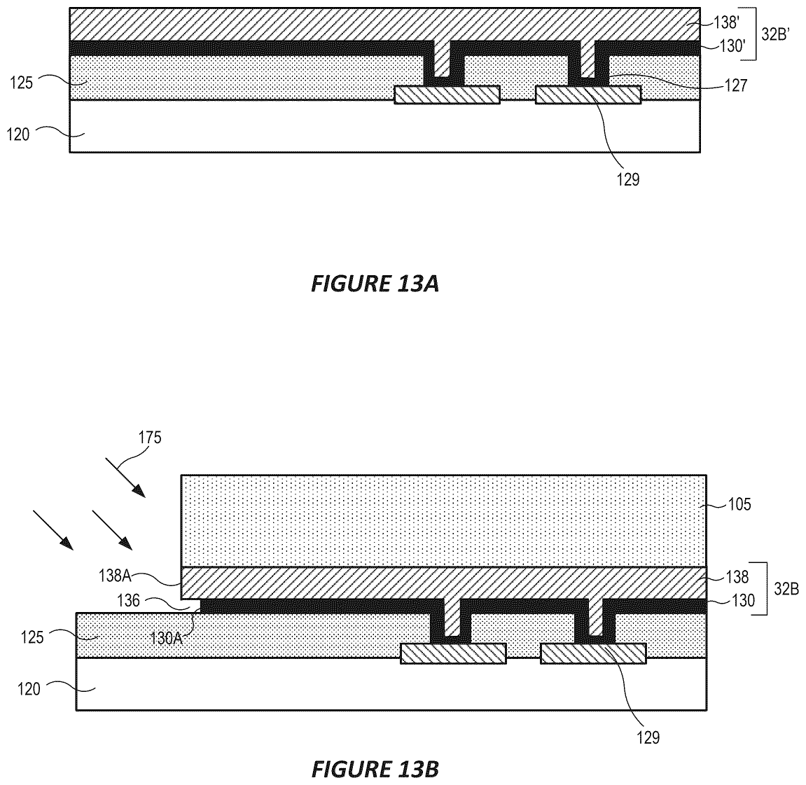

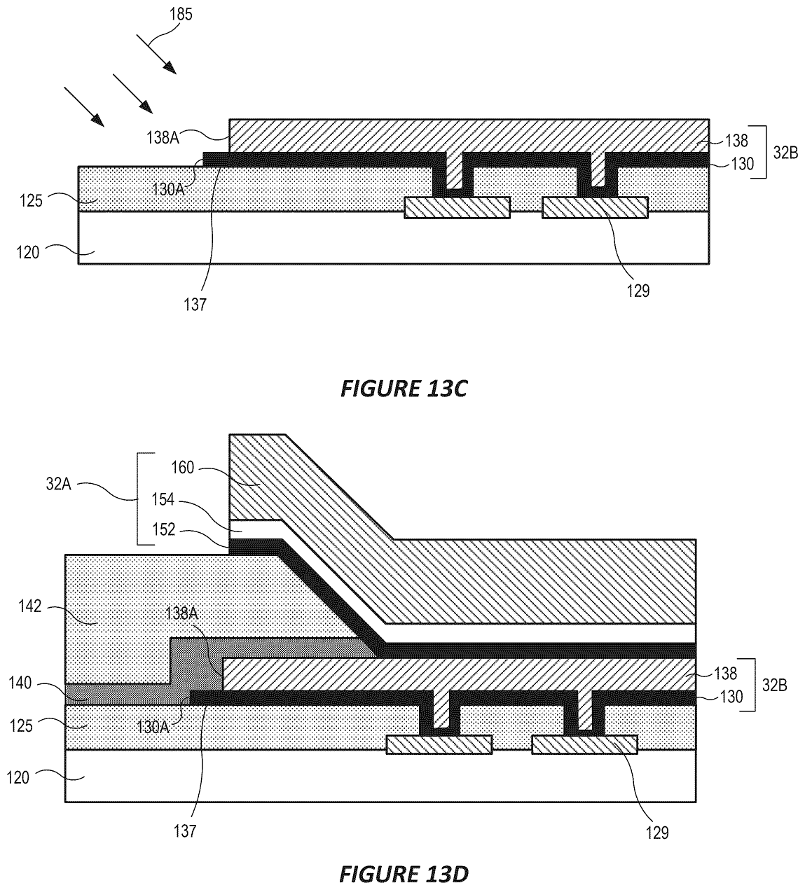

FIGS. 13A-13D illustrate operations of forming a device 100 according to some embodiments. Referring to FIG. 13A, a semiconductor die 120 is provided, for example, as part of a semiconductor wafer prior to dicing. One or more ohmic contacts 129 are formed on the semiconductor die 120, for example, by a metal silicidization process. The ohmic contacts 129 may include additional layers, such as metal layers, metal interconnects, etc., which are not shown for the sake of simplicity. An interlayer dielectric layer 125 is formed over the semiconductor die 120, and a plurality of vias 127 are formed in the interlayer dielectric layer 125 to align with the ohmic contacts 129. A first metal, such as titanium and/or titanium nitride, is then blanket deposited over the interlayer dielectric layer 125, the vias 127 and the exposed portions of the ohmic contacts 129 to form a preliminary intermediate layer 130′. A second metal, such as copper or aluminum copper, is then blanket deposited over the preliminary intermediate layer 130′ to form a preliminary capping layer 138′. The preliminary capping layer 138′ may extend into the vias 127.

Referring to FIG. 13B, when the preliminary capping layer 138′ is an etchable metal, an etch mask 105 is formed over the preliminary capping layer 138′, and the mask 105 is patterned to expose a portion the preliminary capping layer 138′. The exposed portions of the preliminary capping layer 138′ are then etched using a first etch process 175 to expose a portion of the interlayer dielectric layer 125 and define a first metal layer 32B including an intermediate layer 130 and a capping layer 138. In some embodiments, the first etch process 175 may be an anisotropic etch process, such as a wet etch process that uses an etchant such as HF/HNO₃ solution. In other embodiments, the first etch process 175 may include an anisotropic etch process, such as a dry etch process.

If the preliminary capping layer 138′ is a non-etchable layer such as Cu, the etch mask 105 will be polarity inverted, and instead will be a plating mask 105, and the first metal layer 32B will be plated onto the interlayer dielectric layer 125 using the plating mask.

As seen in FIG. 13B, the intermediate layer 130 may become slightly recessed relative to the capping layer 138 during the first etch process 175 (or plating process, in when the first metal layer 32B is non-etchable), resulting in the formation of an overhang or gap 136 beneath the capping layer 138 near an outer edge 138A of the capping layer 138.

Referring to FIG. 13C, the etch mask 105 is removed, and a second, unmasked, etch process 185 is performed to etch back the outer edge 138A of the capping layer 138 to remove any overhang of the capping layer 138 relative to the outer edge 130A of the intermediate layer 130.

The second etch process 115 is selective relative to the intermediate layer 130. That is, the second etch process 185 is chosen so that the exposed portions of the capping layer 138 are removed by the second etch process 185, but the intermediate layer 130 is not affected. For example, the second etch process 185 may be any wet (isotropic) etch process or a dry (anisotropic) etch process that etches the material of the capping layer 138 but is selective relative to the material of the intermediate layer 130 and the interlayer dielectric layer 125.

A typical wet etch for aluminum films is a mixture of 1-5% HNO₃ (nitric acid), 65-80% H₃PO₄ (phosphoric acid), acetic acid (1-5%) for wetting, with the remainder being H₂O.

Some wet etches for Cu include dilute nitric acid, and mixtures of NH₄OH (ammonium hydroxide) and H₂O₂ (peroxide). The aluminum etch described above will also etch Cu at a very high rate.

In some embodiments the capping layer 138 may be etched back just to the point that the outer edge 138A of the capping layer 138 is vertically aligned with the edge 130A of the barrier layer. Thus, in some embodiments, a peripheral edge portion, or protrusion, 137 may not be formed.

Referring to FIG. 13D, the passivation layer 140 (optional) and protective layer 142 are then formed on the device. The passivation layer 140 may be formed on the interlayer dielectric layer 125 and extend up and onto the exposed edge 130A of the intermediate layer 130 (and on to the protrusion 137, if present). The passivation layer 140 further extends up onto the capping layer 138. Because the passivation layer 140 directly contacts at least the exposed edge 130A of the intermediate layer 130, there may be no gap beneath the capping layer 138, and the passivation layer 140 may help to obstruct undesirable migration of metal from the capping layer 138 into the semiconductor die 120, including sensitive portions such as oxide layers of the semiconductor die 120.

An opening is formed in the protective layer 142 and the passivation layer 140, and the second metal layer 32A, including the second barrier layer 152, the seed layer 154 and the bonding layer 160 are formed through the opening onto the capping layer 138. The second metal layer 32A extends up onto the passivation layer 140 and the protective layer 142.

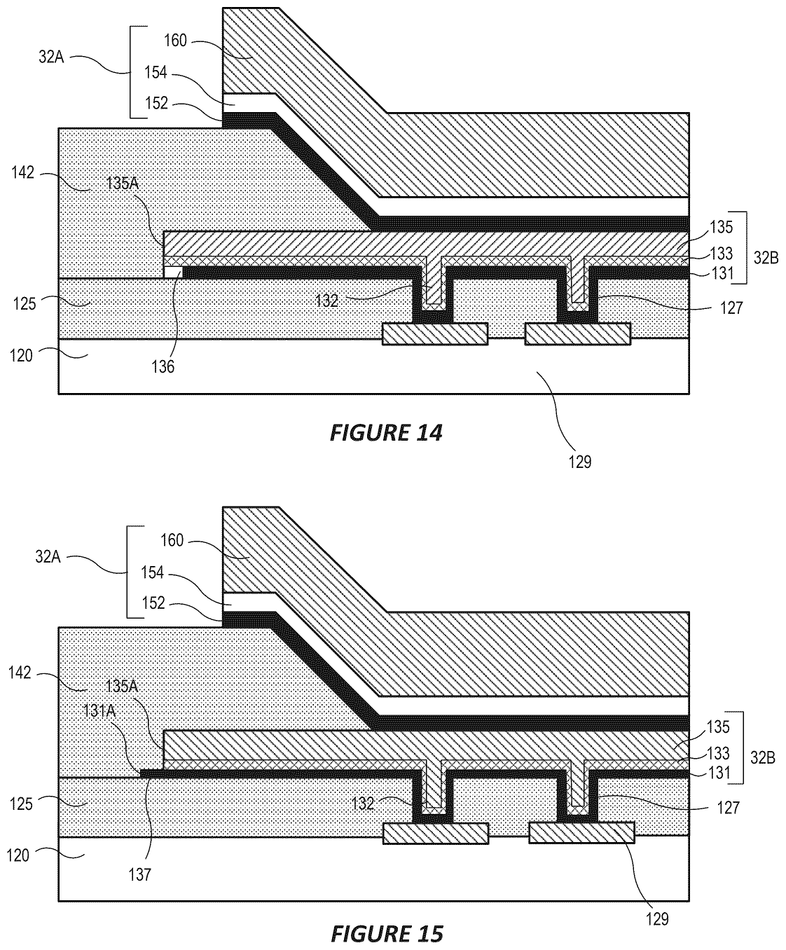

FIGS. 14 and 15 illustrate structures according to further embodiments including structures with (FIG. 14) and without (FIG. 15) a void or gap beneath the edge of the capping layer. For example, in the embodiments of FIGS. 14 and 15, the first metal layer 32B includes a barrier layer 131, a seed layer 133 on the barrier layer 131 and a capping layer 135. The barrier layer 131 may include TiW, and the seed layer 133 and the capping layer 135 may include Cu.

The seed layer 133 may cover the barrier layer 131 and may extend at least partially into the via 127. Referring to FIG. 14, when a second etch is not performed as described above, a gap or void 136 may be formed beneath an edge 135A of the capping layer 135 and the seed layer 133. However, referring to FIG. 15, when the second etch is performed as described above, the capping layer 135 and the seed layer 133 may be etched back to remove the gap 136 and form a protrusion, or foot, 137 in some embodiments.

In the embodiment illustrated in FIGS. 14 and 15, only a single protective layer 142, such as a polyimide layer, is formed on the interlayer dielectric layer 125 to extend onto the edge 131A of the barrier layer and the protrusion 137, if present.

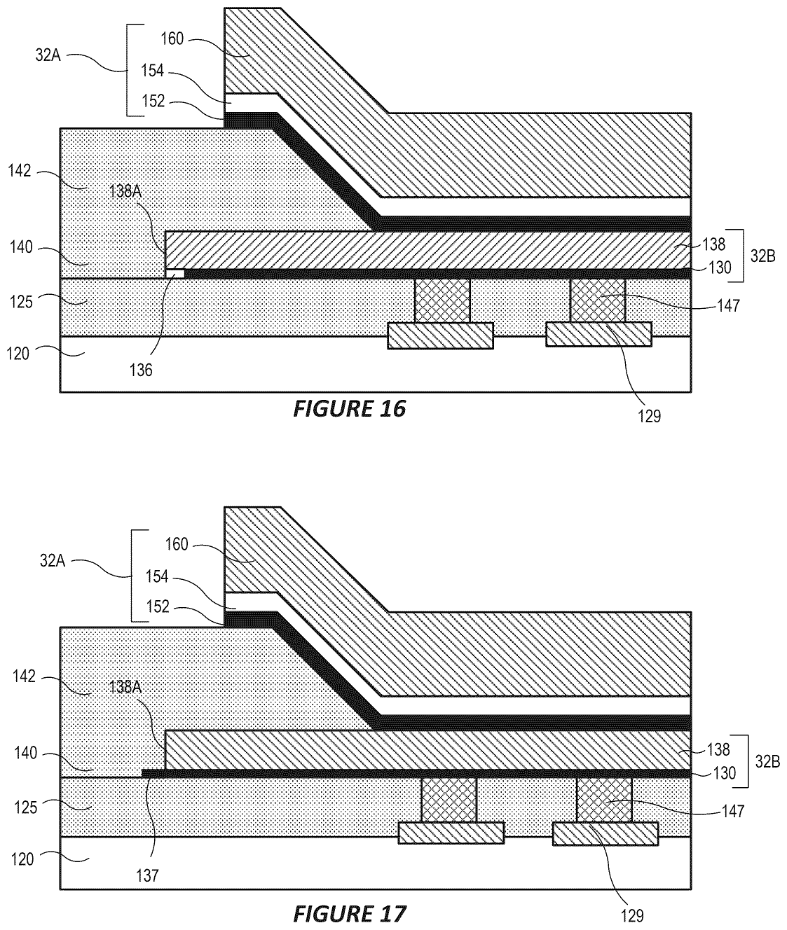

FIGS. 16 and 17 illustrate structures according to further embodiments including structures with (FIG. 16) and without (FIG. 17) a void or gap beneath the edge of the capping layer. For example, in the embodiments of FIGS. 16 and 17, the first metal layer 32B includes an intermediate layer 130 and a capping layer 138. The intermediate layer 130 may include TiW, and the capping layer 138 may include Cu.

In the embodiment illustrated in FIGS. 16 and 17, the vias 127 may be filled with a metal plug 147 including a material such as a tungsten. Accordingly, in the embodiment illustrated in FIGS. 16 and 17, the barrier layer 131 and the capping layer 138 may not extend into the vias 127.

Referring to FIG. 16, when a second etch is not performed as described above, a gap 136 may be formed beneath an outer edge 138A of the capping layer 138. However, referring to FIG. 17, when the second etch is performed as described above, the capping layer 138 may be etched back to remove the gap 136 and form a protrusion, or foot, 137 in some embodiments.

In the embodiment illustrated in FIGS. 16 and 17, only a single protective layer 142, such as a polyimide layer, is formed on the interlayer dielectric layer 125 to extend onto the edge 131A of the barrier layer and the protrusion 137, if present.

While the above-described power semiconductor devices and the other devices described herein are shown as being silicon carbide-based semiconductor devices, it will be appreciated that embodiments of the present inventive concepts are not limited thereto. Instead, the semiconductor devices may comprise any wide bandgap semiconductor that is suitable for use in power semiconductor devices including, for example, gallium nitride-based semiconductor devices, gallium nitride-based semiconductor devices and II-VI compound semiconductor devices.

The inventive concepts have been described above with reference to the accompanying drawings, in which embodiments of the inventive concepts are shown. This inventive concepts may, however, be embodied in many different forms and should not be construed as limited to the embodiments set forth herein. Rather, these embodiments are provided so that this disclosure will be thorough and complete, and will fully convey the scope of the inventive concepts to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present inventive concepts.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the inventive concepts. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the inventive concepts.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present inventive concepts may include additional and/or intervening layers, structures, or elements, and/or particular layers, structures, or elements may be deleted. Although a few exemplary embodiments of the inventive concepts have been described, those skilled in the art will readily appreciate that many modifications are possible in the exemplary embodiments without materially departing from the novel teachings and advantages of the inventive concepts. Accordingly, all such modifications are intended to be included within the scope of the inventive concepts as defined in the claims. Therefore, it is to be understood that the foregoing is illustrative of the present inventive concepts and is not to be construed as limited to the specific embodiments disclosed, and that modifications to the disclosed embodiments, as well as other embodiments, are intended to be included within the scope of the appended claims. The inventive concepts are defined by the following claims, with equivalents of the claims to be included therein.

1. A semiconductor device, comprising:
a semiconductor die; and
a metal contact structure on the semiconductor die, the metal contact structure comprising a first metal layer structure on the semiconductor die;
wherein the first metal layer structure comprises an intermediate layer and a first metal contact layer on the intermediate layer;
wherein an outer edge of the first metal contact layer is inset from an outer edge of the intermediate layer so that a peripheral portion of the intermediate layer extends farther outward than the outer edge of the first metal contact layer.

2. The semiconductor device of claim 1, further comprising a protective layer on the peripheral portion of the first metal contact layer and the outer edge of the intermediate layer.

3. The semiconductor device of claim 2, wherein the protective layer comprises a passivation layer on the peripheral portion of the first metal contact layer and the outer edge of the intermediate layer.

4. The semiconductor device of claim 3, further comprising a polyimide layer on the passivation layer.

5. The semiconductor device of claim 2, wherein the protective layer comprises a polyimide layer (142′) on the peripheral portion of the first metal contact layer and the outer edge of the intermediate layer.

6. The semiconductor device of claim 1, wherein the intermediate layer comprises a first intermediate layer, the metal contact structure further comprising a second metal layer structure on the first metal layer structure, the second metal layer structure comprising a second intermediate layer on the first metal contact layer and a second metal contact layer on the second intermediate layer.

7. The semiconductor device of claim 6, wherein the first intermediate layer and the second intermediate layer comprise titanium nitride, titanium tungsten and/or tantalum nitride.

8. The semiconductor device of claim 7, wherein the first intermediate layer comprises titanium nitride and the second intermediate layer comprises titanium tungsten.

9. The semiconductor device of claim 7, wherein the first metal contact layer and the second metal contact layer comprise copper, and wherein the first intermediate layer and the second intermediate layer comprise titanium tungsten.

10. The semiconductor device of claim 1, wherein the first intermediate layer is formed on an interlayer dielectric layer, wherein the semiconductor device further comprises an ohmic contact on the semiconductor die, and wherein the semiconductor device further comprises a conductive via that electrically connects the first metal contact layer and the ohmic contact.

11. The semiconductor device of claim 10, wherein the intermediate layer and the first metal contact layer extend into the conductive via.

12. The semiconductor device of claim 10, wherein the conductive via comprises a conductive plug.

13. The semiconductor device of claim 12, wherein the conductive plug comprises tungsten.

14. The semiconductor device of claim 1, wherein the first metal contact layer comprises copper, and wherein the intermediate layer comprises titanium nitride, titanium tungsten and/or tantalum nitride.

15. The semiconductor device of claim 14, further comprising a second metal contact layer comprising copper on the first metal contact layer.

16. The semiconductor device of claim 1, wherein the first metal contact layer comprises aluminum copper.

17. A method of forming a semiconductor device, comprising:
providing a semiconductor layer;
providing an interlayer dielectric layer on the semiconductor layer;
providing an intermediate layer on the interlayer dielectric layer;
providing a metal layer on the intermediate layer, wherein an outer edge of the metal layer overhangs an outer edge of the intermediate layer; and
etching the metal layer at least until the outer edge of the metal layer no longer overhangs the outer edge of the intermediate layer.

18. The method of claim 17, wherein etching the metal layer exposes a peripheral portion of the intermediate layer.

19. The method of claim 18, further comprising forming a protective layer on the semiconductor layer, the protective layer contacting the interlayer dielectric layer, the intermediate layer and the metal layer.

20. The method of claim 19, wherein the protective layer comprises a passivation layer on the outer edge of the metal layer and the outer edge of the intermediate layer.

21. The method of claim 20, further comprising forming a polyimide layer on the passivation layer.

22. The method of claim 19, wherein the protective layer comprises a polyimide layer on the peripheral portion of the intermediate layer and the outer edge of the metal layer.

23. The method of claim 17, wherein the intermediate layer comprises a first intermediate layer and the metal layer comprises a first metal layer, the method further comprising:
providing a second metal layer structure on the first metal layer, the second metal layer structure comprising a second intermediate layer on the first metal layer and a second metal layer on the second intermediate layer.

24. The method of claim 23, wherein the first intermediate layer and the second intermediate layer comprise titanium nitride, titanium tungsten and/or tantalum nitride.

25. The method of claim 24, wherein the first intermediate layer comprises titanium nitride and the second intermediate layer comprises titanium tungsten.

26. The method of claim 24, wherein the first metal layer and the second metal layer comprise copper, and wherein the first intermediate layer and the second intermediate layer comprise titanium tungsten.

27. The method of claim 17, wherein the semiconductor device further comprises an ohmic contact on the semiconductor layer, and wherein the semiconductor device further comprises a conductive via that electrically connects the metal layer and the ohmic contact.

28. The method of claim 27, wherein the intermediate layer and the metal layer extend into the conductive via.

29. The method of claim 27, wherein the conductive via comprises a conductive plug.

30. The method of claim 29, wherein the conductive plug comprises tungsten.

31. The method of claim 17, wherein the etching the metal layer comprises isotropically etching the metal layer.

32. A method of forming a semiconductor device, comprising:
providing a semiconductor layer;
providing an interlayer dielectric layer on the semiconductor layer;
providing a preliminary intermediate layer on the interlayer dielectric layer;
providing a preliminary capping layer on the preliminary intermediate layer;
etching the preliminary capping layer and the preliminary intermediate layer to define a capping layer and an intermediate layer, wherein etching the preliminary capping layer and the preliminary intermediate layer causes an outer edge of the capping layer to overhang an outer edge of the intermediate layer; and
etching the capping layer at least until the outer edge of the capping layer no longer overhangs the outer edge of the intermediate layer.

33. The method of claim 32, wherein etching the capping layer exposes a peripheral portion of the intermediate layer.

34. The method of claim 32, further comprising forming a protective layer on the semiconductor layer, the protective layer contacting the interlayer dielectric layer, the intermediate layer and the capping layer.
